(19) United States
(12) Patent Application Publication
(10) Pub. No.: US 2008/0227267 A1
(43) Pub. Date: Sep. 18, 2008

(54) Stop mechanism for trench reshaping process

(76) Inventor: Theodorus Gerardus Maria Oosterlaken, Oudewater (NL)

Correspondence Address: KNOBBE MARTENS OLSON & BEAR LLP, 2040 MAIN STREET, FOURTEENTH FLOOR, IRVINE, CA, 92614, US

(21) Appl. No.: 11/724,548

(22) Filed: Mar. 14, 2007

(51) Int. Cl. H01L 21/76

(52) U.S. Cl. 438/424

(57) ABSTRACT

An opening, such as a trench, on a semiconductor substrate is annealed to smooth edges and corners of the opening. The anneal causes reflow of the material forming the walls of the opening, thereby smoothing out the edges and corners of the opening. After a desired amount of reflow is accomplished, the substrate is exposed to an oxidant such as O₂ or H₂O. The oxidant stops the reflow, thereby preventing undesired excess movement of material.

### FIELD OF THE INVENTION

This invention relates generally to semiconductor processing and, more particularly, to methods for reshaping openings in semiconductor substrates.

### BACKGROUND OF THE INVENTION

Openings, such as trenches, in a substrate are used in the formation of various features during semiconductor processing. For example, trenches can be used to house capacitors or transistor components. In another example, they can be filled with dielectric material to form shallow trench isolation (STI) features, which can be used to insulate electrical devices, such as transistors or capacitors. Sometimes conductive lines (e.g., buried bit lines in memory array) are formed in trenches below other circuitry. As is well known, semiconductor processing is typically employed in the fabrication of integrated circuits, but such processing is also employed in a variety of other fields. For example, semiconductor processing techniques are often employed in the fabrication of flat panel displays using a wide variety of technologies and in the fabrication of microelectromechanical systems (MEMS).

It will be appreciated that the shapes of trenches are important for the proper functioning of the features that are formed using the trenches. For example, a misshapen trench may not function properly for STI, thereby possibly causing shorts or otherwise undermining the reliability of integrated circuits or other electronic devices of which the trenches are a part.

After being formed, trenches can be subjected to a reshaping process to smooth their corners and walls. This reshaping can be accomplished by performing an anneal. For example, with reference to FIG. 1, a substrate 10 is provided with a trench 20. The substrate 10 is then subjected to an anneal. With reference to FIG. 2, the anneal ideally leaves the trench 20 with rounded edges and corners, formed an idealized reshaped trench 22, as illustrated. However, in practice, the anneal may cause an enlargement or change in the dimensions of the trench 20, forming an undesirably deformed trench 24, as shown in FIG. 3. As shown in FIG. 4, in other cases, the anneal can also non-uniformly reshape the trench 20, resulting in a non-symmetrical trench 26 having sharp corners or edges.

It will be appreciated that as the sizes of electronic devices decrease, the sizes of openings in those devices are also decreasing. Consequently, minor deviations in the desired shape of an opening are increasingly significant, since the relative scale of these deviations increases as the sizes of the openings decrease.

Accordingly, there is a need for methods and apparatus that provide improved control over the reshaping of openings such as trenches.

### SUMMARY OF THE INVENTION

According to one aspect of the invention, a method is provided for integrated circuit fabrication. The method comprises providing a semiconductor substrate having a trench in a process chamber. A reducing atmosphere is also provided in the process chamber. The trench is reshaped in the reducing atmosphere in the process chamber by exposing the substrate to a temperature of about 1000° C. or higher. The reshaping of the trench is stopped by flowing an oxidant into the process chamber.

According to another aspect of the invention, a method is provided for semiconductor processing. The method comprises providing an opening in a semiconductor substrate in a process chamber. The substrate is annealed in a reducing or inert atmosphere in the process chamber. An oxidant is subsequently flowed into the reducing or inert atmosphere in the process chamber.

According to yet another aspect of the invention, a method is provided for semiconductor processing. The method comprises annealing a substrate in a process chamber. The substrate having an opening formed in silicon and annealing the substrate reshapes the opening by causing migration of the silicon forming walls of the opening. Migration of the silicon is stopped by flowing a migration stopping agent into the process chamber. Annealing the substrate and stopping migration are performed at a same temperature.

According to another aspect of the invention, a system is provided for processing semiconductor substrates. The system comprises a furnace configured to accommodate a plurality of semiconductor substrates, a source of inert or reducing gas in gas communication with the furnace, a source of oxidant in gas communication with the furnace, and a controller. The controller is programmed to anneal the plurality of semiconductor substrates and to flow the oxidant into the process chamber immediately after annealing the substrates.

### BRIEF DESCRIPTION OF THE DRAWINGS

The invention will be better understood from the detailed description of the preferred embodiments and from the appended drawings, which are meant to illustrate and not to limit the invention and wherein like numerals refer to like parts throughout.

FIG. 1 is a cross-sectional side view of a trench on a substrate, in accordance with the prior art.

FIG. 2 is a cross-sectional side view of the structure of FIG. 1, showing an idealized result after performing a trench reshape process.

FIG. 3 is a cross-sectional side view of the structure of FIG. 2, showing a deformed trench after performing a trench reshape process in accordance with the prior art.

FIG. 4 is a cross-sectional side view of the structure of FIG. 2, showing another deformed trench after performing a trench reshape process in accordance with the prior art.

FIG. 5 is a cross-sectional side view of a trench in a substrate in accordance with preferred embodiments of the invention.

FIG. 6 is a cross-sectional side view of the structure of FIG. 5 after an oxide removal in accordance with preferred embodiments of the invention.

FIG. 7 is a cross-sectional side view of the structure of FIG. 6 during early stages of a trench reshape process in accordance with preferred embodiments of the invention.

FIG. 8 is a cross-sectional side view of the structure of FIG. 7 showing the trench after stopping the reshaping of the trench in accordance with preferred embodiments of the invention.

FIG. 9 is a cross-sectional side view of the structure of FIG. 8 showing the trench after forming a liner over the trench in accordance with preferred embodiments of the invention.

FIG. 10 is a cross-sectional side view of the structure of FIG. 9 showing the trench after filling the trench in accordance with preferred embodiments of the invention.

FIG. 11 is a cross-sectional side view of an exemplary batch reactor in accordance with preferred embodiments of the invention.

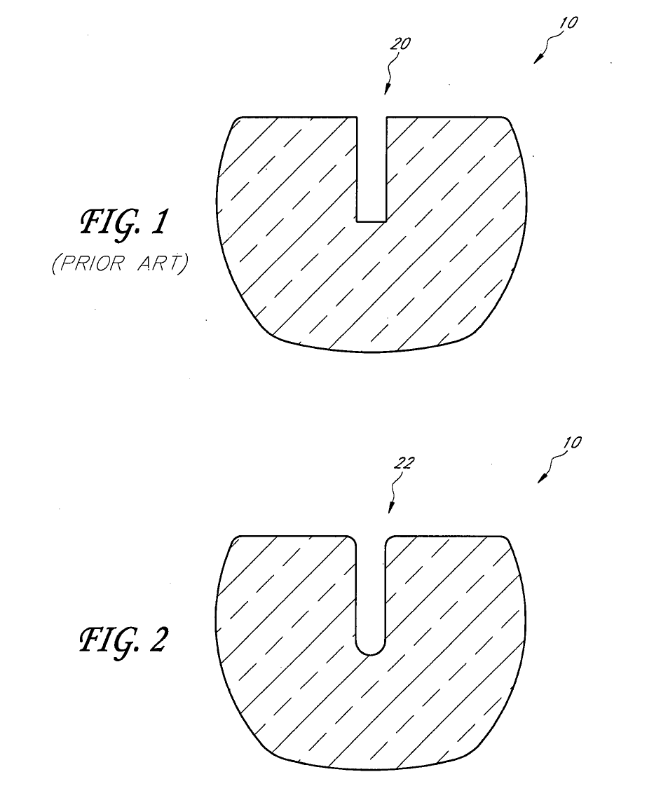

### DETAILED DESCRIPTION OF THE PREFERRED EMBODIMENTS

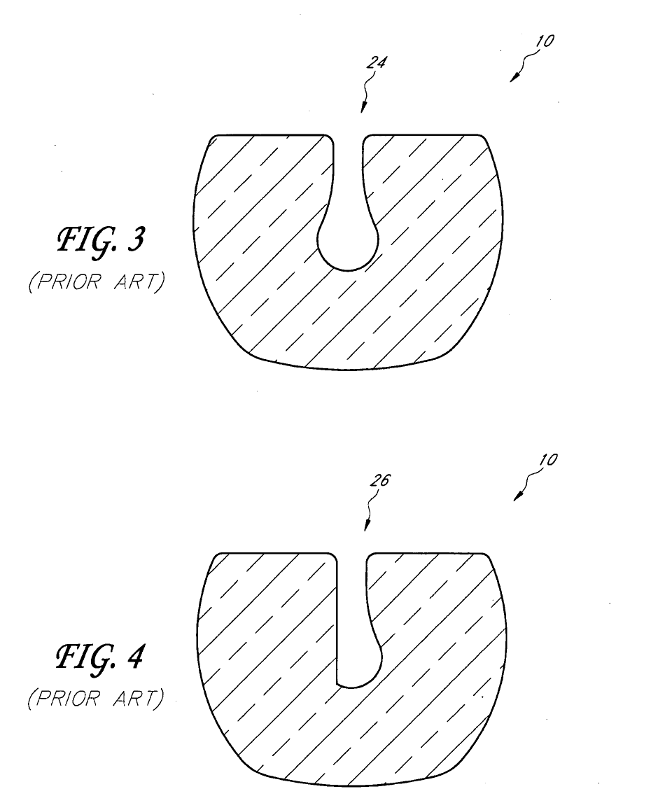

Various factors have been found to contribute to the undesired deformation of openings, or trenches, during a reshaping process. For example, it will be appreciated that trench reshaping typically involves annealing the material forming the walls of the trench. The material is heated to a temperature sufficiently high to cause migration, or reflow, of that material. Stopping the reshaping typically involves cooling the material to stop the migration of the material. However, it is difficult to cool the material instantaneously, especially in a furnace having hot walls, which may retain heat and may have a large thermal mass, making temperature changes slow. Moreover, the temperature needed to start the reflow of the trench material may be higher than that needed to sustain the reflow. As a result, the furnace may need to be cooled from the higher temperature, which can exacerbate difficulties with furnace cooling. Consequently, after reaching an idealized trench shape (FIG. 2), the material can continue to migrate. The reshape can then progress more than desired, as shown in, e.g., FIG. 3. It will also be appreciated that attempting to time the cooling step to account for the time needed to cool the material can result incomplete reshaping of the trench, as shown in, e.g., FIG. 4.

Other complications can also contribute to undesired deformation of trenches. For example, a trench may have an overlying oxide before starting the reshaping process. Oxides are difficult to reshape and are typically removed before starting the reshaping. Oxide removal can involve an anneal in a reducing atmosphere (e.g., an H₂ atmosphere). The oxide removal anneal can be performed at a relatively high temperature, but the temperature is eventually lowered for the cooling step at the end of the reshaping. In some circumstances, the duration of the exposure to the high temperature may not be long enough to remove all the oxide on trench surfaces. The remaining oxide can prevent movement of the material defining the walls of the trench. Reshaping can occur in parts of the trench without overlying oxide, while minimal reshaping occurs in the parts of the trench with overlying oxide. Consequently, with reference to FIG. 4, too much (e.g., the right wall of the illustrated trench) and too little (e.g., the left wall of the illustrated trench) reshaping of a single trench can occur.

Preferred embodiments of the invention advantageously allow for a high degree of control over the trench reshaping process. The material forming the trench is annealed to cause migration of that material. In some embodiments, the anneal is performed in a reducing atmosphere, e.g., a H₂ atmosphere. After a desired degree of trench reshaping is accomplished, the trench reshaping is stopped by exposing the trench to a migration stopping agent. Preferably, the migration stopping agent is preferably an oxidant, such as O₂ or H₂O. In other embodiments, the migration stopping agent is a nitrogen species, such as nitrogen gas. For STI applications, the migration stopping agent is preferably an oxidant. Preferably, the reshaping anneal and the addition of the migration stopping agent occur at about the same temperature. The anneal temperature for trenches formed in silicon material is preferably about 1000° C. or higher, more preferably, about 1100° C. or higher, and can be about 1200° C. or higher. The reshape anneal may also be performed in situ with and immediately subsequent to an oxide removal anneal. Preferably, the reshape anneal and the oxide removal anneal are performed isothermally, although different temperatures may also be used for each anneal.

Advantageously, the migration stopping agent reacts with the material (also called the trench material) forming the walls of the trench to stop movement or migration of the material. For example, the migration stopping agent can form an oxide or nitride upon reaction with the trench material. Where the material defining the trench is silicon, the migration stopping agent can form a reaction product such as silicon oxide or silicon nitride. Advantageously, the reaction product can be utilized in subsequent processing steps. For example, the reaction product can be used as a liner for a subsequently formed shallow trench isolation feature.

Advantageously, because the reshaping can be stopped relatively quickly with the migration stopping agent, any overshoot of the reshape process can be minimized. In addition, because the migration stopping agent is used to stop the reshaping, temperature reduction is not used to stop reshaping in some embodiments. Thus, the trench material can be maintained at a high temperature in a reducing atmosphere for a longer duration than processes in which the material must be cooled to stop the reshaping. As a result, the oxide removal may be more complete.

Moreover, the oxide removal temperature can also be set higher than in processes in which a temperature reduction is used to stop the reshape process. It will be appreciated that the need to cool the trench material can limit the anneal temperature, since a temperature which is too high may not allow cooling at a rate sufficiently quick to stop the reshape process in a timely fashion. Advantageously, in preferred embodiments, as a result of the higher temperature and/or the longer duration of exposure to a high temperature, the removal of any oxide on trench surfaces may be more complete. Advantageously, the subsequent reshaping process can also be more complete without the presence of oxide which can prevent the reshaping.

Reference will now be made to the Figures, wherein like numerals refer to like parts throughout. It will be appreciated that the figures are not necessarily drawn to scale, nor are the various parts of the illustrated structures necessarily drawn to scale relative to other parts of the illustrated structures.

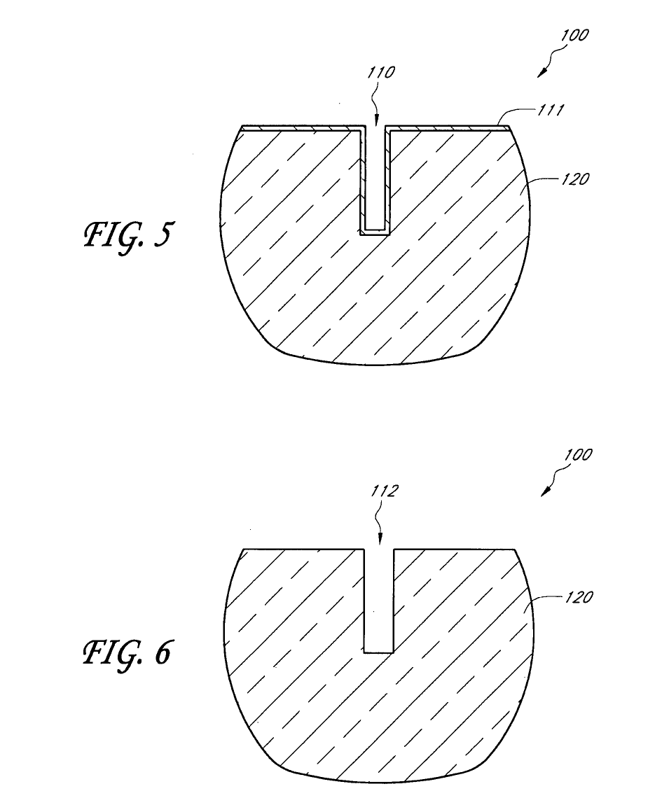

With reference to FIG. 5, a partially-formed electronic device 100 is illustrated. The electronic device 100 can be any device formed using semiconductor processing, including but not limited to integrated circuits, flat panel displays and microelectromechanical systems. The device 100 includes a substrate 120 having a trench 110. In preferred embodiments, at least the parts of the substrate 120 in which the trench 110 is provide is formed of silicon, such that the walls of the trench 110 are also formed of silicon.

The trench 110 can be formed by various methods known in the art. For example, a mask layer can be formed over the substrate 120 and the mask layer can be patterned to define an opening corresponding to the trench 110. The substrate 120 can subsequently be etched to form the trench 110. Preferably, the etch is a directional or anisotropic etch, such as a reactive ion etch (RIE). Overlying mask layers may subsequently be removed.

After the formation of the trench 110, the substrate 120 may be transferred to a process or reaction chamber for subsequent anneal processes. For example, the substrate 120 can be transferred to a furnace. Preferably, the furnace can accommodate 25 or more substrates, which has advantages for increasing throughput. An example of suitable furnaces are the A400™ and the A412™ reactors, commercially available from ASM International, N.V. of Bilthoven, The Netherlands.

It will be appreciated that the surfaces of the trench 110 can include an oxide 111, which may form incidentally due to exposure to oxidant during, e.g., transfer of a substrate between different reaction chambers, or which is purposefully formed by deposition of an oxide or by thermal oxidation of the substrate 120. Preferably, the oxide 111 is removed to facilitate later reflow of the substrate material defining the walls of the trench 110. It will be understood that the term “reflow” is used generically to indicate the movement or migration of material. No process for formation of the material is implied.

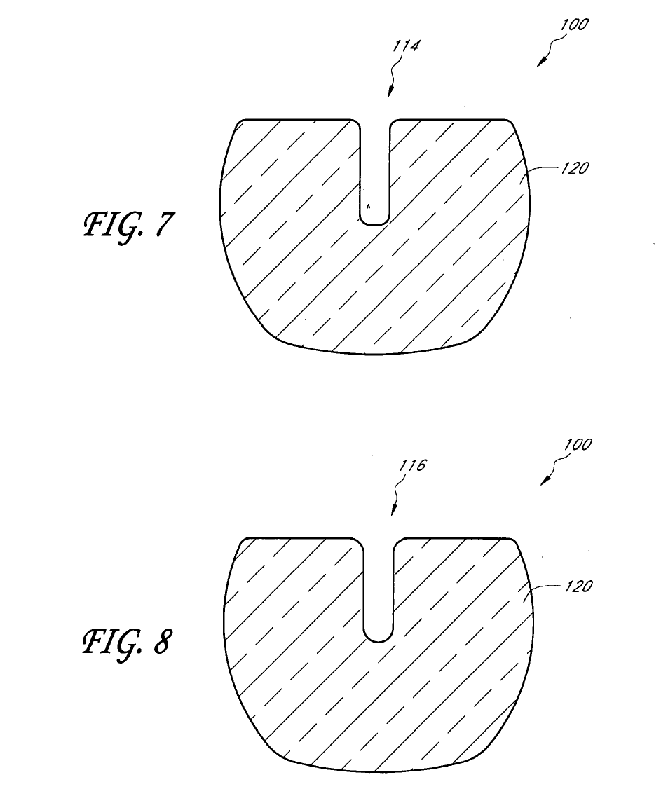

With reference to FIG. 6, the substrate 120 is annealed to remove oxide on surfaces of the trench 110 (FIG. 5). As shown in FIG. 6, the oxide removal can slightly increase the depth and width of the trench 110, thereby resulting in the trench 112. The oxide removal is preferably accomplished by exposing the substrate 120 to a reducing atmosphere, e.g., an H₂ atmosphere. While the oxide removal can be accomplished by various methods known in the art, the oxide removal is preferably accomplished in a furnace, e.g., a hot-wall vertical furnace, and H₂ is preferably flowed into the process chamber of the furnace to expose the substrate 120 to a reducing atmosphere.

With reference to FIG. 7, the trench 112 is annealed at a temperature sufficiently high to cause migration or movement of the material forming the walls of the trench (also called a reshape anneal). The reshape anneal may be performed in the same process chamber as that used for the oxide removal, in which case the substrate 120 may simply be kept in the process chamber after the oxide removal anneal. In other embodiments, the substrate 120 may be loaded into a process chamber and subjected to a reshape anneal without specifically performing an oxide removal anneal (although it will be appreciated that some oxide removal can nevertheless occur during the reshape anneal).

The movement of the material forming the walls of the trench 112 may also be referred to as a material reflow and rounds the edges and corners of the trench 112, thereby forming the trench 114. When the material is silicon, the reshape anneal temperature is preferably about 1000° C. or higher, more preferably about 1100° C. or higher, and can be about 1200° C. or higher in some embodiments. In some embodiments, the atmosphere in the process chamber during the reshape anneal is the same as that used for oxide removal, e.g., H₂ can constitute the process chamber atmosphere.

In other embodiments, the reshape anneal is performed with an inert, e.g., argon, atmosphere in the process chamber. Where an oxide removal is performed before the reshape anneal, the reducing atmosphere of the oxide removal may be purged with argon before performing the reshape anneal.

It will be appreciated that the reshape anneal can be performed at the same or a different temperature than the oxide removal anneal. Advantageously, as noted above, the temperature of the oxide removal anneal can be performed at the same high temperature as the reshape anneal, which also facilitates complete removal of any oxide. In addition, the reshape anneal can be performed isothermally with the oxide removal anneal, thereby also facilitating complete removal of the oxide by effectively extending the duration of the oxide removal anneal. In other embodiments, the reshape anneal temperature can be reduced relative to the oxide removal temperature.

With reference to FIG. 8, the reshape anneal is continued for a duration sufficient for the trench 114 (FIG. 7) to assume a desired shape. It will be appreciated that the duration can be a predetermined duration which has been previously found (e.g., empirically, by test runs of the reshaping process) to reshape the trench 114 to a desired degree. After performing the reshape anneal for the desired predetermined duration, the trench preferably assumes a smoothly rounded shape, with smoothly rounded corners and edges, thereby forming the trench 116, as illustrated in FIG. 8.

Once the desired shape is assumed, e.g., after performing the reshape anneal for the desired predetermined duration, a migration stopping agent is flowed into the process chamber. Without being limited by theory, it is believed that the migration stopping agent reacts with the material forming the sidewalls of the trench 116 to stop migration or reflow of atoms of that material. The migration stopping material is preferably an oxidant, e.g., O₂ and/or H₂O. The oxidant forms an oxide, which is resistant to the movement of atoms caused by the reflow.

Advantageously, the sidewalls of the trench 116 are preferably maintained substantially straight. In some embodiments, such as for STI, the trench 116 can have a depth of about 800 Å or more, preferably about 1000 Å or more, and a width of about 200 Å or more, preferably about 500 Å or more.

Where the process chamber has an atmosphere that includes H₂, O₂ flowing into the process chamber can react with the hydrogen gas to form H₂O. Thus, flowing O₂ into the process chamber can also result in the trench 116 being exposed to H₂O.

In other embodiments, the migration stopping agent can be a nitrogen-containing species, such as nitrogen gas. It will be appreciated that the nitrogen-containing species can form a nitride on surfaces of the trench.

While different process chambers may be used for the oxide removal and the reshape anneal, the oxide removal and the reshape anneal are preferably performed in the same chamber, which has advantages for processing efficiency and quality of process results. Use of oxygen and hydrogen in the same reactor creates a serious risk of explosion, however. Consequently, performing the oxide removal and the reshape anneal in situ is non-trivial due to operational safety concerns and to the risk of damage to the reactor. This risk may be minimized by flowing the oxygen into the process chamber at a concentration sufficiently low to prevent explosions. In some embodiments, the flows of oxygen, hydrogen and/or argon into the chamber are regulated such that the concentration of oxygen in a hydrogen-containing mixture in the chamber remains below about 4% by volume.

In some preferred embodiments, the oxygen is flowed from a source container which stores oxygen at a concentration which is non-explosive in the presence of any amount of hydrogen under operating conditions of the reshape anneal. Preferably, the oxygen container contains about 10% O₂ by volume, more preferably about 4% O₂ by volume, diluted in a non-reactive gas such as argon. Advantageously, the mixture housed in the container can be flowed into a process chamber without concern for explosions, irrespective of the flow rates of the oxidant. Moreover, a non-explosive mixture will also remain non-explosive no matter what the level of hydrogen is in the reactor, even in the face of mass flow controller failures or valve failures. This advantageously adds a layer of safety not present in systems which simply regulate the flow of oxygen into a process chamber from a container containing relatively undiluted oxygen.

In some embodiments, the process chamber may be purged with argon to establish an argon atmosphere in the chamber before flowing the migration stopping agent in to the process chamber. Advantageously, because argon does not react with oxygen, a higher concentration of oxygen may be flowed into the process chamber, which may have advantages for more quickly stopping the trench reflow.

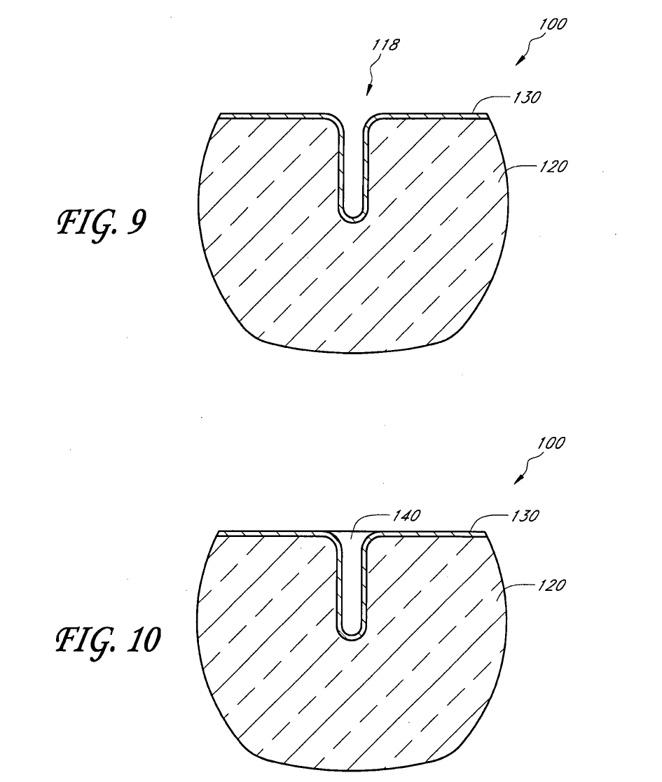

With reference to FIG. 9, one or more additional layers of material can be formed overlying the trench. A liner 130 can be formed. In some embodiments, the liner 130 is an oxide formed by oxidation of the substrate 120. Where the substrate 120 is formed of silicon, the liner 130 is formed of silicon oxide. In some embodiments, O₂ is flowed into a process chamber having an argon atmosphere to form a thermal oxide. In other embodiments, a nitrogen-containing gas such as NH₃ or N₂ is flowed into the process chamber to form a nitride liner (e.g., a silicon nitride layer). In yet other embodiments, oxide and/or nitride liners can be deposited overlying the trench, e.g., by CVD. It will be appreciated that the formation of the liners can be selective, e.g., by providing a material which inhibits formation of the liner on surfaces over which liner formation is not desired.

With reference to FIG. 10, the trench 118 can be filled with a material 140. Where the trench 118 is used to form a STI structure, the material 140 is preferably a dielectric, e.g., an oxide. While illustrated with a single liner 130 for ease of description and illustration, it will be appreciated that multiple liners can be formed in the trench 118 before the filling the trench.

In addition to forming STI structures, it will be appreciated that the preferred embodiments can be applied to form various other structures utilizing trenches or openings. For example, embodiments of the invention can be utilized in the formation of trench capacitor structures, transistor structures, etc.

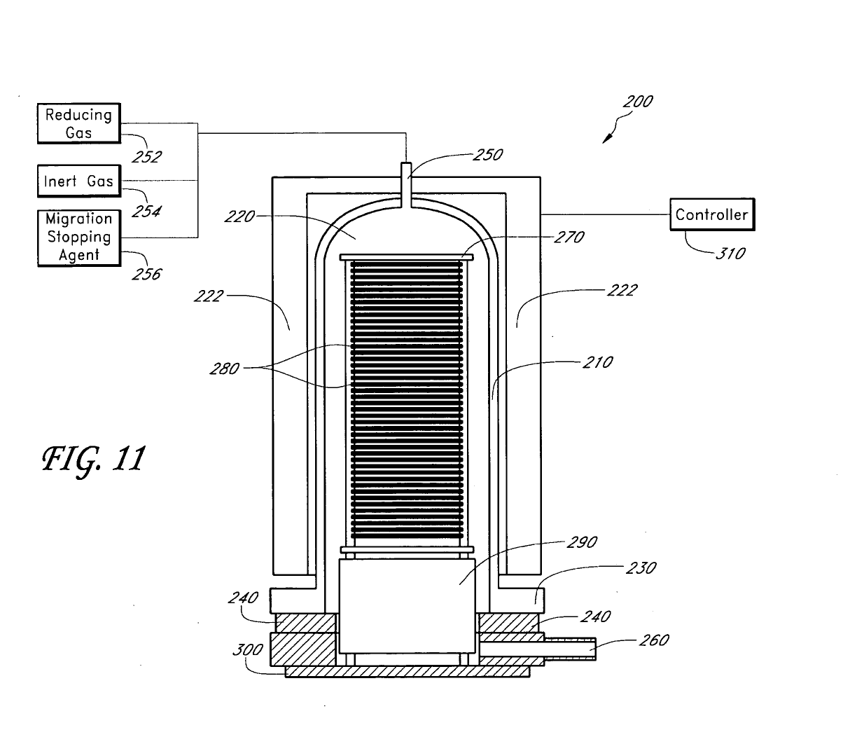

An noted above, the various processing steps noted above can be performed in a batch reactor. FIG. 11 illustrates an exemplary batch reactor or vertical furnace 200. A process tube 210 defines a reaction or process chamber 220 in the interior of the reactor 200. Heaters 222 heat the process chamber 220. The lower end of the tube 210 terminates in a flange 230, which mechanically seals the chamber 220 by contact with a lower support surface 240. Process gases can be fed into the reaction chamber 220 through a gas inlet 250 at the top of the chamber 220 and evacuated out of the chamber 220 through a gas outlet 260 at the bottom of the chamber 220. The gas inlet 250 is connected by a gas line to various gas sources, including a source 252 of reducing gas, a source 254 of inert gas, and a source 256 of a migration stopping agent. The reaction chamber 220 accommodates a wafer boat 270 holding a stack of vertically spaced substrates or wafers 280. The wafer boat 270 is supported on a pedestal 290, which is supported on a door 300.

The reactor 200 also includes a controller 310. The controller 310 is programmed to perform the various in situ processing steps discussed above. For example, the controller 310 is programmed to heat the process chamber to a desired temperature, by controlling the heaters 222. The controller 310 is programmed to heat the process chamber 220 to an oxide removal temperature and to a reshape anneal temperature, which may be the same temperature as the oxide removal temperature. During the oxide removal anneal, the controller 310 is programmed to flow reducing gas from the reducing gas source 252 into the process chamber 220 in some embodiments and to flow inert gas from the inert gas source 254, without flowing reducing gas, into the process chamber 220 in other embodiments. The controller 310 is programmed to anneal the plurality of semiconductor substrates 280 for a duration sufficient to reshape trenches in the substrates 280 to a desired shape. The controller 310 is programmed to then flow the migration stopping agent (e.g., an oxidant) from the source 256 into the process chamber 220 immediately after annealing the substrates 280 for the duration sufficient to reshape the trenches, thereby stopping the trench reshaping.

In some embodiments, the flow rates of various gases may be as follows: reducing gas is flowed into the process chamber at between about 2 slm and about 50 slm, more preferably between about 10 slm and about 20 slm during an oxide removal anneal; the migration stopping agent O₂ is flowed into the process chamber at between about 1 sccm and about 25 slm, more preferably between about 400 sccm and about 800 sccm to stop the trench reshaping. Preferably, the concentration of oxidant in the process chamber is between about 0.01 and about 4% by volume, more preferably between about 0.1 and about 1% by volume. The inert gas can be flowed at between about 2 and about 50 slm, more preferably, between about 10 and about 20 slm into the process chamber simultaneously with the migration stopping agent. In some embodiments, the oxide removal anneal is performed for between about 1 and about 3600 seconds, more preferably between about 10 and about 600 seconds, before introduction of the migration stopping agent into the process chamber.

It will be appreciated by those skilled in the art that various omissions, additions and modifications can be made to the processes described above without departing from the scope of the invention, and all such modifications and changes are intended to fall within the scope of the invention, as defined by the appended claims.

We claim:

1. A method for integrated circuit fabrication, comprising:
providing a semiconductor substrate having a trench in a process chamber;
providing a reducing atmosphere in the process chamber;
reshaping the trench in the reducing atmosphere in the process chamber by exposing the substrate to a temperature of about 1000° C. or higher; and
stopping reshaping the trench by flowing an oxidant into the process chamber.

2. The method of claim 1, wherein providing the semiconductor substrate comprises providing an oxide overlying a surface of the trench, wherein reshaping the trench in the reducing atmosphere removes the oxide.

3. The method of claim 1, wherein the substrate is heated to about 1100° C. or higher during reshaping.

4. The method of claim 1, wherein reshaping and stopping reshaping are performed substantially isothermally.

5. The method of claim 1, wherein reshaping comprises maintaining a H₂ atmosphere in the process chamber.

6. The method of claim 1, wherein the process chamber is substantially free of oxidant during reshaping, wherein stopping reshaping comprises starting a flow of O₂ into the process chamber.

7. The method of claim 1, further comprising depositing a dielectric into the trench after stopping reshaping.

8. The method of claim 7, further comprising forming a layer of material on sidewalls of the trench after reshaping and before depositing the dielectric.

9. The method of claim 8, wherein forming the layer of material comprises oxidizing the sidewalls to form an oxide layer.

10. The method of claim 9, wherein the sidewalls are formed of silicon, wherein oxidizing the sidewalls forms a silicon oxide layer.

11. A method for semiconductor processing, comprising:
providing an opening in a semiconductor substrate in a process chamber;
annealing the substrate in a reducing or inert atmosphere in the process chamber; and
subsequently flowing an oxidant into the reducing or inert atmosphere in the process chamber.

12. The method of claim 11, wherein annealing the substrate comprises reflowing material forming walls of the opening.

13. The method of claim 12, wherein subsequently flowing the oxidant stops flowing of the material.

14. The method of claim 12, wherein silicon defines walls of the opening, wherein flowing material comprises flowing the silicon.

15. The method of claim 12, wherein annealing the substrate is performed at about 1000° C. or higher.

16. The method of claim 11, wherein subsequently flowing the oxidant is performed upon the opening assuming a desired shape.

17. The method of claim 11, wherein the oxidant is flowed from an oxidant source containing oxygen in an amount non-explosive in the presence of any concentration of hydrogen under conditions for exposing the substrate.

18. The method of claim 11, wherein annealing the substrate and subsequently flowing the oxidant are performed isothermally.

19. The method of claim 11, wherein annealing the substrate is performed at a first process chamber temperature, further comprising reducing the process chamber temperature to a second temperature before exposing the substrate to the oxidant.

20. The method of claim 19, wherein the first temperature is about 1000° C. or higher.

21. The method of claim 20, wherein the second temperature is about 1000° C. or lower.

22. The method of claim 11, wherein the substrate is a silicon wafer.

23. The method of claim 11, wherein the opening is a trench.

24. The method of claim 23, further comprising forming a shallow trench isolation structure in the trench.

25. The method of claim 11, wherein annealing the substrate is comprises maintaining a H₂ atmosphere in the process chamber, wherein subsequently flowing the oxidant comprises maintaining an Ar atmosphere in the process chamber.

26. A method for semiconductor processing, comprising:
annealing a substrate in a process chamber, the substrate having an opening formed in silicon, wherein annealing the substrate reshapes the opening by causing migration of the silicon forming walls of the opening; and
stopping migration of the silicon by flowing a migration stopping agent into the process chamber, wherein annealing the substrate and stopping migration are performed at a same temperature.

27. The method of claim 26, wherein the migration stopping agent is an oxidant.

28. The method of claim 27, wherein exposing the substrate forms an oxide layer at a surface of the substrate.

29. The method of claim 26, wherein the migration stopping agent is a nitrogen containing species.

30. The method of claim 29, wherein the migration stopping agent is nitrogen gas or NH₃ gas.

31. The method of claim 26, wherein the material forming the walls of the opening is silicon.

32. The method of claim 26, wherein stopping migration and annealing the substrate are preformed at a same temperature.

33. The method of claim 32, wherein stopping migration and annealing the substrate are preformed at about 1100° C. or higher.

34. The method of claim 33, wherein stopping migration and annealing the substrate are preformed at about 1200° C. or higher.

35. The method of claim 26, wherein annealing the substrate rounds edges and corners of the opening while maintaining a sidewalls of the opening substantially straight.

36. The method of claim 26, wherein the opening has a depth of about 800 Å or more.

37. The method of claim 36, wherein the opening has a depth of about 1000 Å or more.

38. The method of claim 36, wherein the opening has a width of about 200 Å or more.

39. The method of claim 38, wherein the opening has a width of about 500 Å or more.

40. The method of claim 26, wherein subjecting the semiconductor substrate is performed in a reducing atmosphere.

41. The method of claim 26, further comprising filling the trench with a dielectric material.

42. A system for processing semiconductor substrates, comprising:
a furnace configured to accommodate a plurality of semiconductor substrates;
a source of inert or reducing gas in gas communication with the furnace;
a source of oxidant in gas communication with the furnace; and
a controller programmed to anneal the plurality of semiconductor substrates, the controller further programmed to flow the oxidant into the process chamber immediately after annealing the substrates.

43. The system of claim 42, wherein the controller is programmed to anneal the plurality of semiconductor substrates for a duration sufficient to reshape trenches in the substrates to a desired shape, wherein the controller is further programmed to flow the oxidant into the process chamber immediately after annealing the substrates for the duration sufficient to reshape the trenches.

44. The system of claim 42, wherein the source of oxidant comprises a container storing oxygen at a level that is non-explosive in the presence of any amount of hydrogen under operating conditions for reshaping the trenches.

45. The system of claim 44, wherein the container holds about 10% O₂ by volume.

46. The system of claim 45, wherein the container holds about 4% O₂ by volume.

47. The system of claim 42, wherein the controller is programmed to anneal substrates at 1000° C. or more.

48. The system of claim 47, wherein the controller is programmed to flow oxidant into the process chamber while heating the process at a same temperature as a temperature of the anneal.

49. The system of claim 42, wherein the trenches are formed in silicon material.

50. The system of claim 42, wherein the furnace is a vertical furnace.

51. The system of claim 50, wherein the furnace is sized and equipped to accommodate 25 or more substrate.
